(19) United States
(12) Patent Application Publication
(10) Pub. No.: US 2008/0123866 A1
(43) Pub. Date: May 29, 2008

(54) Hearing instrument with acoustic blocker, in-the-ear microphone and speaker

(76) Inventors: Elizabeth L. Rule, Hamilton (CA); Stephen W. Armstrong, Burlington (CA)

Correspondence Address: VAN DYKE, GARDNER, LINN & BURKHART, LLP, SUITE 207, 2851 CHARLEVOIX DRIVE, S.E., GRAND RAPIDS, MI, 49546, US

(21) Appl. No.: 11/605,917

(22) Filed: Nov. 29, 2006

(51) Int. Cl. H03B 29/00

(52) U.S. Cl. 381/71.6

(57) ABSTRACT

A hearing instrument includes a main housing, an in-the-ear-canal sound receiving unit, and a sound emitting unit. The sound emitting unit may be located completely in the ear canal or may be linked to the ear canal by an acoustical tube. An acoustic blocker separates the sound emitting unit and sound receiving unit. The main housing is configured to be located outside of the ear canal and includes processing circuitry that is operable to process signals. The acoustic blocker is configured to at least substantially occlude the ear canal and acoustically isolate the sound emitting unit from the sound receiving unit.

### FIELD

The technology described in this patent document relates generally to the field of hearing instruments. More particularly, the technology described herein relates to hearing instrument systems with one or more microphones located in the ear canal.

### BACKGROUND

Most hearing instruments have one or more microphones that are located in the main housing of the hearing instrument. The main housing may be situated in the outer ear (ITE), behind the ear (BTE), in the ear canal (ITC) or completely in the ear canal (CIC). For ITC and CIC hearing instruments, the microphone is located at the outer end of the hearing instrument, either just within the ear canal or just outside the ear canal. Hearing instruments are also known that provide a behind the ear (BTE) main housing with a microphone on a stem that extends down behind the tragus of the ear.

These types of devices may take some advantage of the natural acoustic environment of the outer ear, as it acts as a funnel for bringing sound to the microphone. However, the larger of these conventional instruments do not take further advantage of the natural acoustics of the ear, which provides for an amplified natural funneling of sound. Furthermore, for CIC and ITC hearing aids, their small size and location may limit the functions and processing capabilities that are available.

BTE hearing instruments are also known that include both a speaker and a microphone in the ear canal. Such a device is disclosed in U.S. Pat. No. 5,987,146. However, the previously known BTE hearing instruments that have a speaker and microphone in the ear canal are open-ear devices. If the hearing instrument wearer has low frequency hearing loss, an open fitting hearing instrument will not be very effective. In an open fitting hearing instrument much of the low frequency sounds escape from the ear and do not reach the ear canal at an amplitude that is easily audible. For example, if the hearing aid wearer wants to listen to music or watch television wirelessly, then they would need to have a closed fitting hearing instrument in order to hear the low frequency sounds.

The contrast between open and closed type hearing instruments is illustrated in FIG. 1, which is a graph showing closed vs. open fitting hearing aids. The low amplitude portion in the open hearing instrument graph indicates the above noted deficiency of open hearing instruments in the low frequency (bass) region of the audible spectrum.

Another deficiency of in-the-ear-canal speaker and microphone hearing instruments is that they require processor intensive feedback canceling routines to prevent the feedback effect caused by having the speaker and microphone near each other.

### BRIEF DESCRIPTION OF THE DRAWINGS

FIG. 1 is a graph of the performance of open and closed hearing instruments in decibels plotted versus frequency of sound.

FIG. 2 is an example hearing instrument with an in-the-ear-canal speaker and microphone.

FIG. 3 is an example hearing instrument with an in-the-ear-canal speaker tube and microphone.

FIG. 4 is an example hearing instrument with an in-the-ear-canal speaker and microphone, and auxiliary microphone.

FIG. 5 is an example hearing instrument with an in-the-ear-canal speaker tube and microphone, and auxiliary microphone.

FIG. 6 is an example hearing instrument with an in-the-ear-canal microphone, a cochlear implant, and auxiliary microphone.

FIG. 7 depicts several example flanged acoustic blockers.

FIG. 7a is a transparent view of an example flanged acoustic blocker.

FIG. 8 depicts several example foam acoustic blockers.

FIG. 9 is an example of a custom molded acoustic blocker.

FIG. 10 is a circuit schematic for an example hearing instrument having an in-the-ear-canal microphone and auxiliary microphone.

FIG. 11 is a block diagram of an example hearing instrument showing a more-detailed example of communications circuitry.

FIG. 12 is a functional diagram of an example baseband processor for a hearing instrument.

FIG. 13 is an example hearing instrument with an in-the-ear-canal microphone, speaker and an extra microphone located behind the acoustic blocker

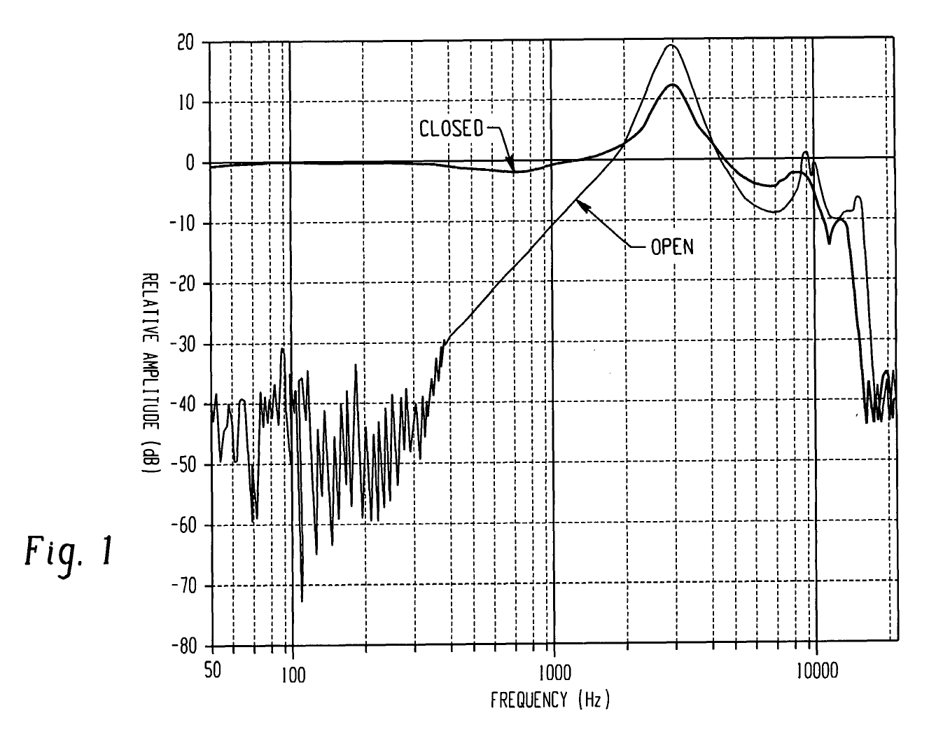

### DETAILED DESCRIPTION

Examples are provided herein of a closed hearing instrument that mitigates feedback, has an in-the-ear microphone and speaker, and utilizes a BTE shell. These examples realize at least the following benefits over the prior art: good low-frequency hearing amplification, less feedback, and a reduced need for feedback canceling, while also taking advantage of the natural acoustic funneling and amplification of the ear.

Example closed-type hearing instruments having a speaker and a microphone placed in the ear canal are described herein. The placing of the microphone in the ear canal enables the hearing instrument to receive and process sounds that have been funneled through the outer ear and a portion of the ear canal. This microphone placement permits the natural acoustics of the ear to affect the sounds reaching the hearing instrument, thereby enabling the hearing instrument to more accurately produce the sound that an unassisted ear would normally hear. The speaker is also placed in the ear, behind an acoustic blocker that substantially closes the ear canal and isolates the speaker from the microphone.

The microphone may be connected by a wire to an example BTE main housing. More space is provided in the BTE unit for housing the processing circuitry and any input devices or communications circuitry, than, for example, a conventional CIC or ITC hearing instrument.

Example hearing instruments are also disclosed that incorporate an in-the-ear microphone and speaker with an auxiliary microphone that is located in the main housing. The processing circuitry in the main housing is configured to receive and process the signals from the two microphones and resolve the signals to provide directionally enhanced hearing assistance and/or enhanced feedback canceling.

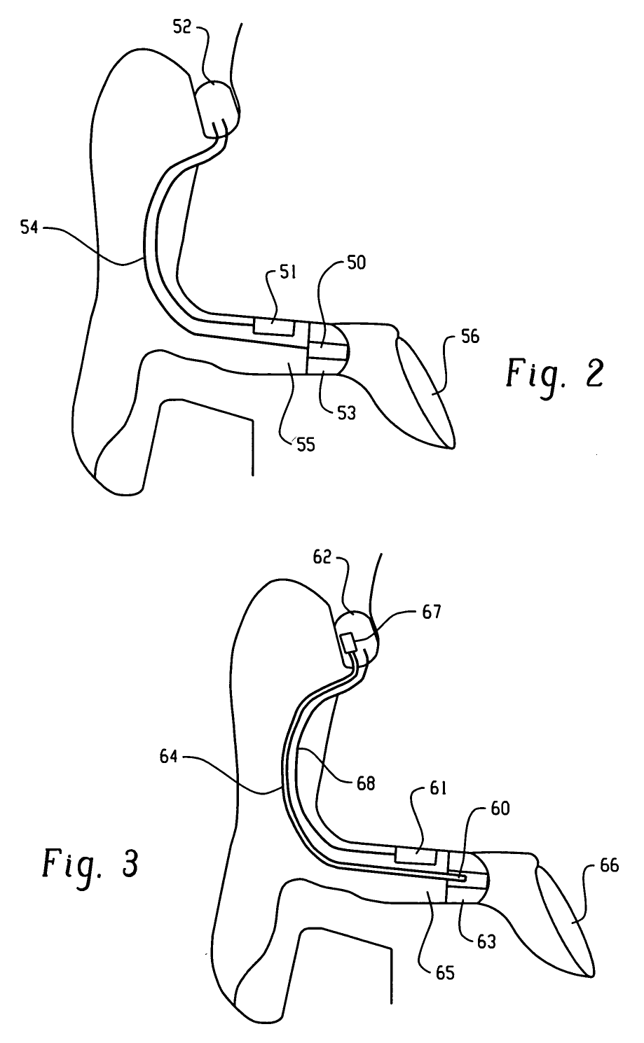

Turning now to the figures, FIG. 2 depicts an example hearing instrument that includes an in-the-ear speaker 50 and microphone 51 and a BTE unit 52. The speaker 50 is housed in an acoustic blocker 53 that serves to isolate the speaker 50 from the microphone 51. The microphone and speaker are connected to the BTE unit 52 by wires 54.

In order to isolate the speaker 50 and microphone 51 and thereby help prevent feedback problems, the acoustic blocker 53 at least substantially occludes the ear canal 55. This occlusion also allows for better hearing assistance in the low-frequency range, as detailed in the background section. The term “at least substantially occludes” means the ear canal is sealed at a minimum to an extent that the problem with feedback from an in-the-ear microphone is appreciably reduced, and at a maximum, the ear canal may also be completely sealed.

Occluding the ear canal 55 may also have the undesirable effect of causing an amplification of the user's own voice within the ear canal 55. The acoustic blocker 53 may have a small opening that functions to mitigate this negative effect of occlusion. The undesirable occlusion effect may also be mitigated by placing the acoustic blocker at the bony portion of the ear canal 55.

In this example, the speaker 50 is housed in the acoustic blocker 53. The acoustic blocker is described in detail in FIGS. 8-10 and below. In other examples, the speaker 50 may be placed outside of the acoustic blocker 53 so that the speaker 50 is nearer the ear drum 56 than the acoustic blocker.

The microphone 51 is situated completely within the ear canal 55 so as to take advantage of the natural acoustic effects of the ear. Sound received from the microphone 51 in this location will have been funneled by the ear to produce an amplified and more natural sound signal than what might be obtained from a microphone that is placed outside the ear canal 55, such as in a BTE unit. By placing the microphone in the ear canal 55, the hearing instrument user will receive a better quality sound that is more similar to what they would hear naturally if they did not require hearing assistance. In one example, the microphone 51 is placed 1-15 mm within the ear canal 55. The exact depth of placement in the ear will vary according to the individual user's ear canal; however, depths between 5 and 10 mm may be preferable than smaller or greater depths.

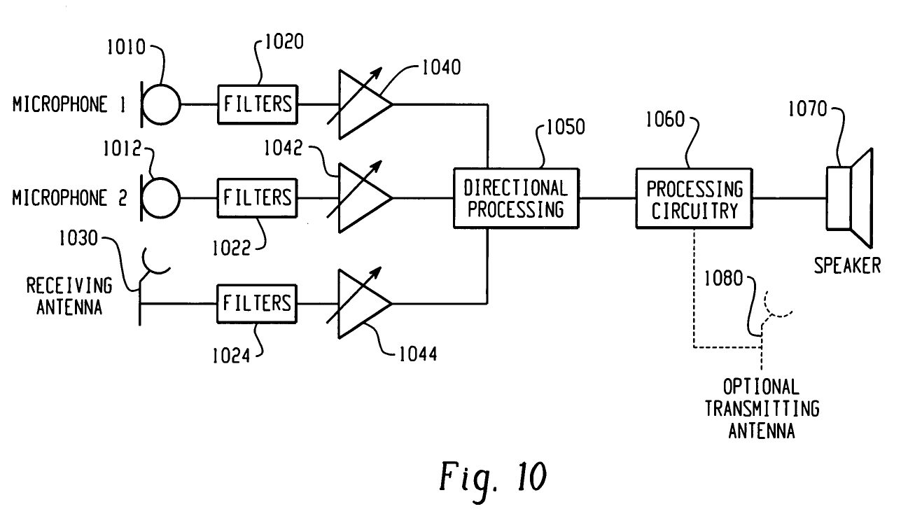

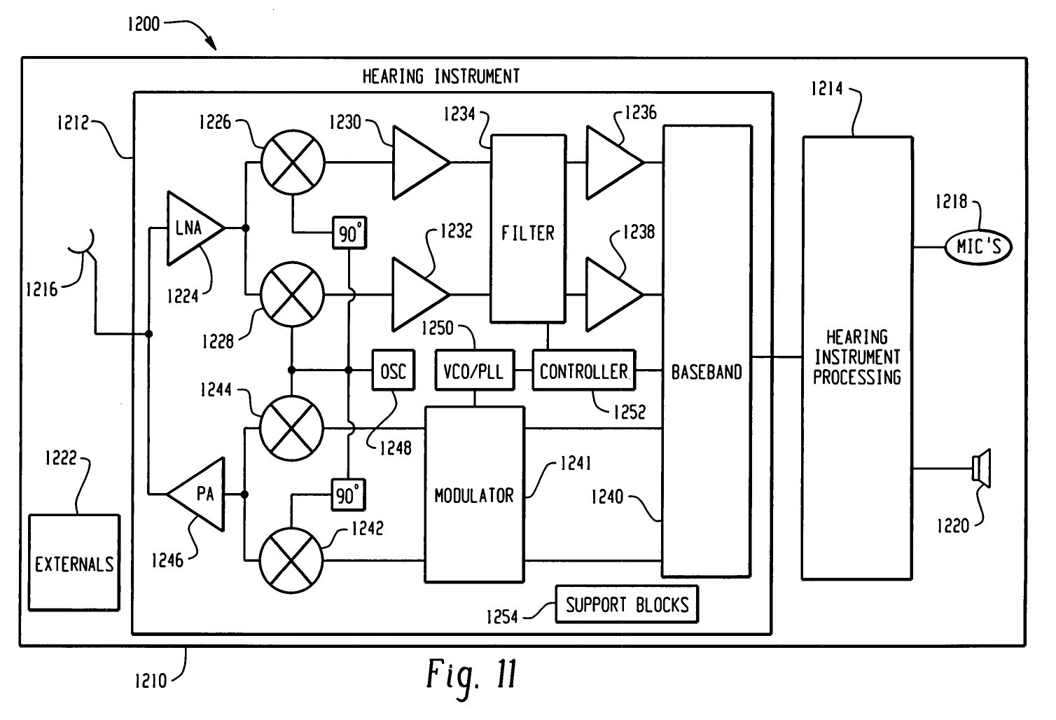

The BTE unit 52, is configured to be situated at the top and behind the user's ear. This unit houses processing and communications circuitry, for example the circuitry as shown in FIGS. 10-12. In other examples, a unit housing the processing and communications circuitry could be located in places other than behind the ear, such as in the pinna of the ear (but not blocking the ear canal), on the user's clothing, or some other location that is proximate to the user.

FIG. 3 is an alternative to the example of FIG. 2 wherein a speaker acoustic tube 64 is used instead of wiring. In the example of FIG. 3, the open end of a speaker tube 60 is housed in the acoustic blocker 63. The speaker tube 64 runs from the end of the speaker tube 60 in the acoustic blocker 63 to a speaker 67 that is housed in the BTE unit 62. Sounds emitted by the speaker 67 are transmitted to the ear canal 65 through the speaker tube 64 and emitted out of the end of the speaker tube 63. The microphone 61 has a wired connection 68 as in the example of FIG. 2.

Moving the speaker 67 from the ear canal 65 into the BTE unit 62 allows for a smaller object, the end of the speaker tube 60, to be placed in the ear canal 65. This may provide better user comfort. It may also allow the use of a larger, better quality speaker 67 because there are less size constraints in the BTE unit 62 than in the ear canal 65 itself.

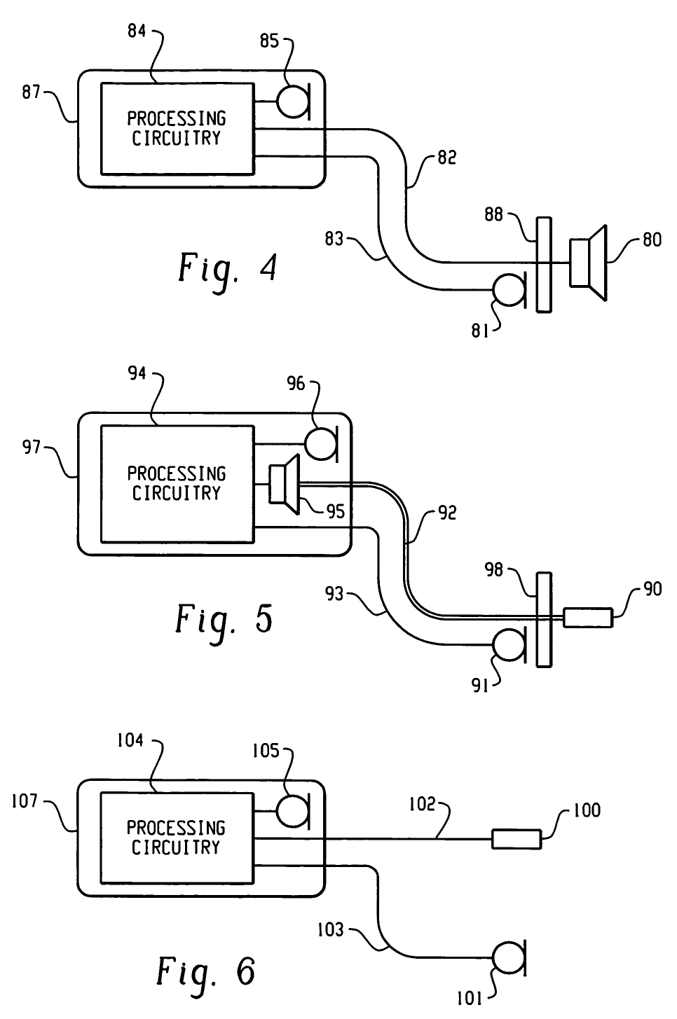

FIG. 4 depicts an example hearing instrument system that includes an auxiliary microphone 85 that is located outside the ear canal in an example exterior unit 87. The example exterior unit 87 also includes processing circuitry 84, and in other examples, may also include communications circuitry. The processing circuitry is coupled to the auxiliary microphone 85, and is also coupled to an in-the-ear-canal speaker 80 and microphone 81 by speaker and microphone wires 82, 83. An acoustic blocker 88 separates the speaker 80 and the microphone 81 and at least substantially seals the ear canal (as described above).

The auxiliary microphone 85 is a second sound input source that may function to provide directional hearing assistance. Depending on the location of the microphone 85, the processing circuitry 84 can process the sound received from the auxiliary microphone 85 and provide a signal to the speaker 80 that gives the user enhanced directional hearing assistance. This feature may be further incorporated with a second hearing instrument for the user's opposite ear, and the two hearing instruments may be linked (e.g., wirelessly linked through communications circuitry).

The auxiliary microphone 85 may also be used in conjunction with the processing circuitry 84 to provide improved feedback cancellation. In this example operation, the signal received by the auxiliary microphone 85 is compared with the signal received by the in-the-ear microphone 81 by the processing circuitry 84. Feedback that may be received from the in-the-ear microphone 81 as a result of its proximity to the speaker 80 is then recognized and eliminated by the processing circuitry.

The exterior unit 87 may be configured to rest behind the ear or in the pinna of the ear (so long as it does not block the ear canal). The exterior unit may also be located in other locations, such as on the user's clothing or some other area that is proximate to the user.

FIG. 5 is an alternative to the example of FIG. 4 that has a speaker acoustic tube 93, instead of wiring. In the example of FIG. 5, the open end of a speaker tube 90 is located on one side of an acoustic blocker 98. The speaker tube 93 runs from the end of the speaker tube 90 to a speaker 95 that is housed in an exterior unit 97. Sounds emitted by the speaker 95 are transmitted through the speaker tube 93 and emitted out of the end of the speaker tube 90. The microphone 91 has a wired connection 82 as in the example of FIG. 4. There is also an auxiliary microphone in the exterior unit 97, as there was in the example of FIG. 4.

FIG. 6 is an example of an alternative transduction system that utilizes the in-the-ear microphone technology described above in combination with the auxiliary microphone technology. Alternative transduction includes bone conduction, middle ear implant, and cochlear implant systems. For example, a cochlear implant is configured to be surgically implanted to stimulate the user's cochlea directly. The cochlear implant 100 is connected by wire 102 to processing circuitry 104 that is located in an exterior unit 107. An in-the-ear microphone 101 is configured to be located within the ear canal of a user and is connected by wire 103 to the processing circuitry 104. The external unit 107 also contains an auxiliary microphone 105. In the same manner, other alternative transduction systems may be incorporated in the technology disclosed herein.

An alternative transduction unit may also be combined with an acoustic speaker. In this dual-mode example, the acoustic speaker is in communication with the processing circuitry 104 and is operable to transmit sounds to the ear in conjunction with the alternative transduction unit.

The example alternative transduction system includes the benefits of more natural sound collection from the in-the-ear microphone 101 and directional hearing assistance from the auxiliary microphone 105. An acoustic blocker is not needed in this example, since there is no benefit to be gained in sound quality from occluding the ear, and there is no problem with feedback from the proximity of a speaker.

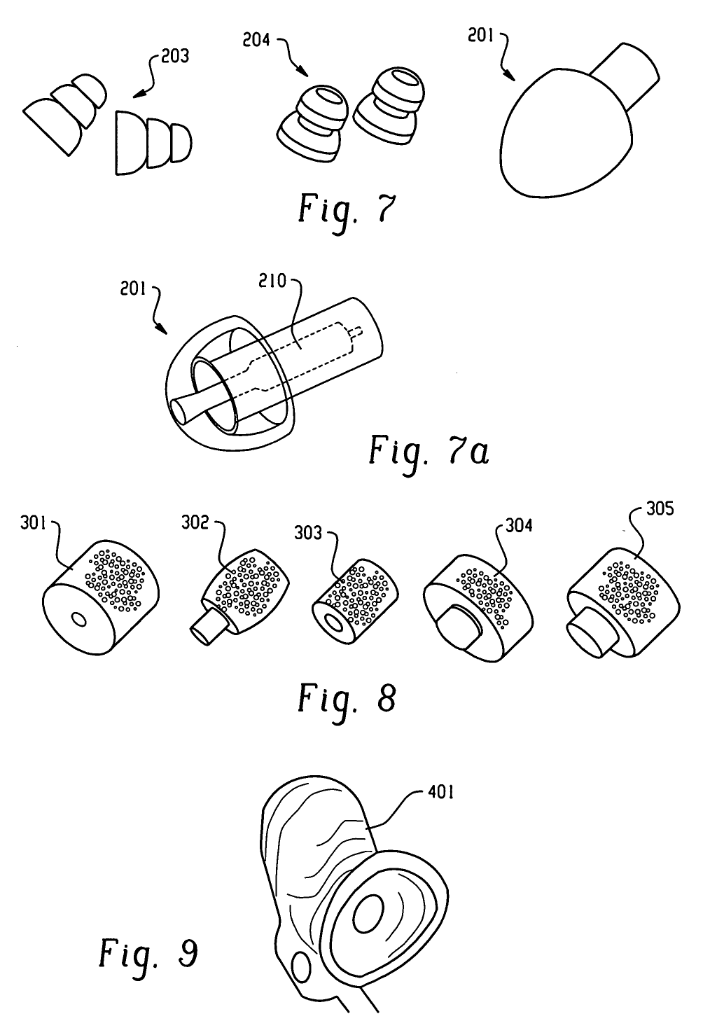

FIG. 7 depicts example flanged acoustic blockers that may be used with the example hearing systems disclosed herein. The example single-flanged acoustic blocker 201 has a single flange that is curved away in a hemisphere from the tip that is configured to face the ear drum. As shown in FIG. 7a, the single-flanged acoustic blocker 201 has a center opening 210 that extends through the longitudinal axis of the acoustic blocker 201. The in-the-ear-canal speaker that is mentioned above can be housed in the opening 210, or a speaker wire or tube can be run through this opening 210. Double- and triple-flanged acoustic blockers 202, 203 may also be used to provide improved sealing or user comfort. The double- and triple-flanged acoustic blockers 202, 203 may also have center openings like the example single-flanged acoustic blocker. Each of these example acoustic blockers are made of a compressible material such as rubber.

FIG. 8 depicts a variety of foam acoustic blockers 301, 302, 303, 304, 305, each of which are depicted with a center opening that could house an in-the-ear-canal speaker or function as a throughway for a wire or acoustic tube.

FIG. 9 depicts a custom made acoustic blocker 401 that has a center opening running through it. A custom acoustic blocker can be made by taking a mold of the user's ear and fashioning a piece that will conform precisely to the contours of the user's ear. This may increase user comfort over the flanged and foam acoustic blockers.

Alternatively, acoustic blockers with no center opening could be utilized, and the wire connecting the in-the-ear-canal speaker to the processing circuitry could run between the side of the user's ear canal and the blocker. However, this is likely to reduce user comfort. Another optional feature for each of the example acoustic blockers, is a small opening that functions to mitigate the negative effect of occlusion.

FIG. 10 is a block diagram of an example processing, communications, and beam-forming circuitry that may be utilized with the example hearing instruments described above. First and second microphones 1010, 1012, are coupled to first and second microphone filters 1020, 1022. One of the first and second microphones 1010, 1012 may be located in the ear canal and the other may be located in a BTE unit. A receiving antenna 1030 is also coupled to a filter 1024. The receiving antenna 1030 may wirelessly receive streaming audio signals from an external source such as a hearing instrument located on the opposite ear or some other external source. The filters 1020, 1022, 1024 operate to shape the signals received from the first and second microphones 1010, 1012 so that the two microphone signals match each other, and so that input received from the antenna 1030 matches the microphone signals.

In this example, amplifiers 1040, 1042, 1044 apply a variable gain to the output from each of the filters 1020, 1022, 1024. The gain element may be incorporated as part of the filters 1040, 1042, 1044 in other examples.

The directional processing circuitry 1050 receives the shaped and amplified signals from the filters, and performs further processing to directionally enhance the signal, such as applying time delays and weighted combinations of the signals.

The directional processing circuitry 1050 produces a combined signal that is further processed by the processing circuitry 1060 before being transmitted to the user through the speaker 1070 or transmitted wirelessly by the transmitting antenna 1080. The processing circuitry may provide feedback cancellation to help remedy feedback caused by having the speaker and the microphone proximately located in the ear canal. Other typical hearing instrument processing is performed with this circuitry. Additionally, hearing instrument calibration and set-up may be performed by the processing circuitry.

The transmitting antenna 1080 could, in an alternate example, be the same as the receiving antenna 1030. This alternate example would prevent simultaneous sending and receiving of signals, however it would reduce size requirements. The processed signal could be transmitted to a hearing instrument on the user's opposite ear. It could also be transmitted to an exterior device such as a computing instrument for performance evaluation and testing procedures. The receiving and transmitting antennas 1030, 1080 may also be used to communicate with the hearing instrument to configure it wirelessly.

In another example, the communications circuitry and antenna are not present. In this example, the hearing instrument can be configured or tested by manually interfacing the instrument with a computing device.

FIG. 11 is a block diagram of an example hearing instrument 1200 showing a more-detailed example of processing and communications circuitry. The example hearing instrument 1200 includes an RF communication module 1212, a hearing instrument processor 1214, an antenna 1216, one or more hearing instrument microphones 1218, a hearing instrument speaker 1220, and one or more external components 1222 (e.g., resistive and reactive circuit components, filters, oscillators, etc.) As illustrated, the RF communication module 1212 and the hearing instrument processor 1214 may each be implemented on a single integrated circuit, but in other examples could include multiple integrated circuits and/or external circuit components.

The RF communication module 1212 includes a baseband processor 1240 and communications circuitry. The communications circuitry includes a transmit path and a receive path. The receive path includes a low noise amplifier (LNA) 1224, a down conversion quadrature mixer 1226, 1228, buffering amplifiers 1226, 1228, an I-Q image reject filter 1234 and a slicer 1236, 1238. The transmit path includes a modulator 1241, an up conversion quadrature mixer 1242, 1244 and a power amplifier 1246. The receive and transmit paths are supported and controlled by the baseband processor 1240 and clock synthesis circuitry 1248, 1250, 1252. The clock synthesis circuitry includes an oscillator 1248, a phase locked loop circuit 1250 and a controller 1252. The oscillator 1248 may, for example, use an off chip high Q resonator (e.g., crystal or equivalent) 1222. The frequency of the phase locked loop circuit 1250 is set by the controller 1252, and controls the operating frequency channel and frequency band. The controller 1252 may, for example, select the operating frequency channel and/or frequency band of the system. Also included in the RF communication module 1212 are support blocks 1254, which may include voltage and current references, trimming components, bias generators and/or other circuit components for supporting the operation of the transceiver circuitry.

In operation, an RF signal received by the antenna 1216 is amplified by the LNA 1224, which feeds the down conversion mixer 1226, 1228 to translate the desired RF band to a complex signal. The output of the down conversion mixer 1226, 1228 is then buffered 1230, 1232, filtered by the image reject filter 1234 and slicer 1236, 1238 and input to the baseband processor 1240. The baseband processor 1240 performs baseband processing functions, such as synchronizing the incoming data stream, extracting the main payload and any auxiliary data channels (RSSI and AFC information), and performing necessary error detection and correction on the data blocks. In addition, the baseband processor 1240 decompresses/decodes the received data blocks to extract the sound signal.

Outgoing sound and/or control signals may be encoded and formatted for RF transmission by the baseband processor 1240. In the case of outgoing sound signals, the baseband processor 1240 may also perform sound compression functions. The processed signal is modulated to an RF carrier by the modulator 1241 and up conversion mixer 1242, 1244. The RF signal is then amplified by the power amplifier 1246 and transmitted over the air medium by the antenna 1216.

The hearing instrument processor 1214 functions to time delay signals received from the one or more microphones 218, and may perform traditional hearing instrument processing functions to compensate for the hearing impairments of a hearing instrument user, along with the binaural processing functions described herein. The hearing instrument processor 1214 may also perform other signal processing functions, such as directional processing, occlusion cancellation, or other functions.

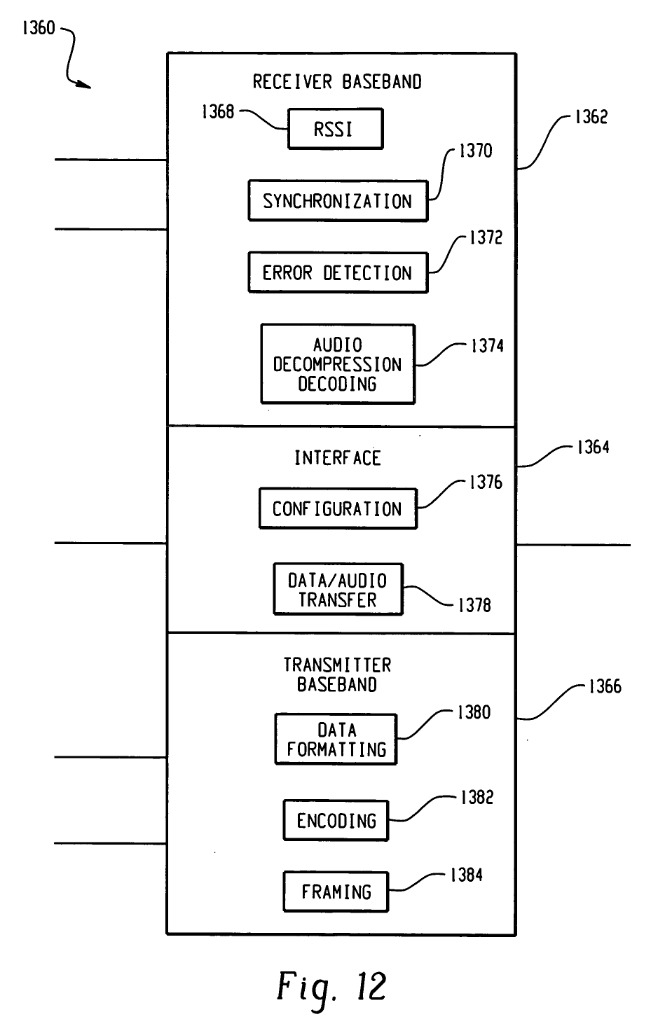

FIG. 12 is a functional diagram of an example baseband processor 1360 for a hearing instrument. The baseband processor 1360 may perform receiver baseband processing functions 1362, interface functions 1364 and transmitter baseband processing functions 1366. The illustrated baseband processor 1360 includes two receiver inputs, two interface input/outputs, and two transmitter outputs, corresponding to the input/outputs to the baseband processor 1240 shown in FIG. 12. It should be understood, however, that other input/output configurations could be used.

The receiver baseband processing functions 1362 include signal level baseband functions 1368, 1370, such as a synchronization function 1370 to synchronize with the incoming data stream, and a data extraction function 1368 for extracting the payload data. Also included in the receiver functions 1362 are an error detection function 1372 for detecting and correcting errors in the received data blocks, and a sound decompression decoding function 1374 for extracting a sound signal from the received data blocks.

The transmitter baseband processing functions 1366 include data formatting 1380 and framing 1384 functions for converting outgoing data into an RF communication protocol and an encoding function 1382 for error correction and data protection. The RF communication protocol may be selected to support the transmission of high quality audio data as well as general control data, and may support a variable data rate with automatic recognition by the receiver. The encoding function 1382 may be configurable to adjust the amount of protection based on the content of the data. For example, portions of the data payload that are more critical to the audio band from 100 Hz to 8 kHz may be protected more than data representing audio from 8 kHz to 16 kHz. In this manner, high quality audio, although in a narrower band, may still be recovered in a noisy environment. In addition, the transmitter baseband processing functions 1366 may include an audio compression function for compressing outgoing audio data for bandwidth efficient transmission.

The interface functions 1364 include a configuration function 1376 and a data/sound transfer function 1378. The data/sound transfer function 1378 may be used to transfer data between the baseband processor 1360 and other circuit components (e.g., a hearing instrument processor) or external devices (e.g., computer, CD player, etc.) The configuration function 1376 may be used to control the operation of the communications circuitry. For example, the configuration function 1376 may communicate with a controller 1352 in the communications circuitry to select the operating frequency channel and/or frequency band.

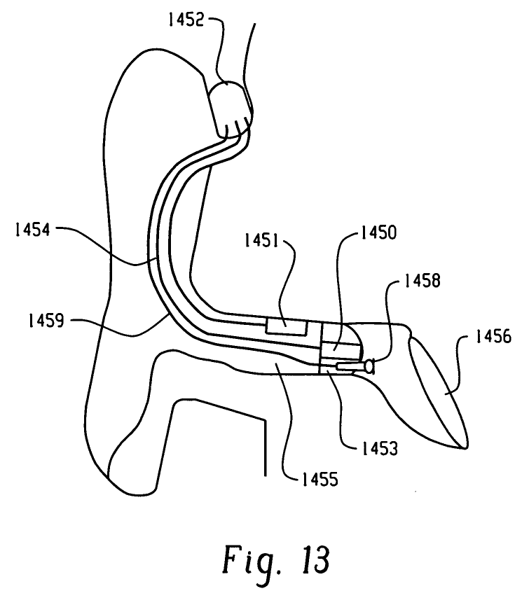

This written description uses examples to disclose the invention, including the best mode, and also to enable a person skilled in the art to make and use the invention. The patentable scope of the invention may include other examples that occur to those skilled in the art. For example, instead of having the microphone in the ear canal and connected to the BTE by a wire; the microphone may be housed in the BTE, but have an acoustic tube linking the microphone to an in-the-ear-canal location. Another variation of the technology disclosed herein is a way to minimize or eliminate the undesirable occlusion effect of the closed-ear hearing instrument through the use of processing circuitry. As shown in FIG. 13, an example hearing instrument system incorporating occlusion effect canceling algorithms includes an extra microphone 1458 that is positioned behind the acoustic blocker 1453. The extra microphone 1458 in this example is partially imbedded in the acoustic blocker 1453 with the receiving end facing the ear drum 1456. The extra microphone 1453 receives sound that is transmitted by the speaker 1450 and that is affected by occlusion. The extra microphone 1453 then transmits the sound to processing circuitry in a BTE unit 1452 through a wire 1459. The processing circuitry applies occlusion cancellation algorithms to the signal, and the processed signal is then transmitted through the speaker 1450. In this way, the occlusion effect is remedied by canceling the occlusion induced sounds that occur in the blocked-off portion of the ear canal 1455 with the signal from the speaker 1450. Further details of occlusion-effect cancellation processing are described in commonly owned U.S. Pat. No. 6,937,738, entitled “Digital Hearing Aid System.” This patent is hereby incorporated by reference.

A further variation of the example hearing instrument with occlusion effect cancellation circuitry includes processing circuitry located in the ear canal 1455. In this example, the processing circuitry is dedicated to performing the occlusion effect cancellation and the extra microphone is connected directly to the dedicated processing circuitry. The speaker 1450 is wired to both the dedicated processing circuitry and the BTE unit 1452. In other examples, additional hearing instrument processing, such as amplification, feedback cancellation may be performed by the in-the-ear circuitry.

It is claimed:

1. A hearing instrument comprising:
a main housing configured to be located outside of the ear canal, the main housing including processing circuitry operable to process signals;
a sound receiving unit configured to be located completely within the ear canal;
a sound emitting unit configured to be located completely within the ear canal; and
an acoustic blocker configured to at least substantially occlude the ear canal and isolate the sound emitting unit from the sound receiving unit;
the sound receiving unit and the sound emitting unit being in communication with the processing circuitry.

2. The hearing instrument of claim 1, wherein the sound receiving unit is a microphone or an acoustic tube coupled to a microphone.

3. The hearing instrument of claim 1, where the sound emitting unit is a speaker or an acoustic tube coupled to a speaker.

4. The hearing instrument of claim 1, wherein the main housing includes a communications unit.

5. The hearing instrument of claim 4, wherein the communications unit is configured to transmit or receive wireless signals.

6. The hearing instrument of claim 4, wherein the communications unit is configured to transmit and receive wireless signals.

7. The hearing instrument of claim 6, wherein the communications unit is configured to wirelessly communicate with another hearing instrument.

8. The hearing instrument of claim 7, wherein communication between the hearing instruments is utilized to assist in feedback cancellation.

9. The hearing instrument of claim 7, wherein communication between the hearing instruments is utilized to assist in directional processing.

10. A hearing instrument comprising:
a main housing configured to be located outside of an ear canal, the main housing including processing circuitry operable to process signals;
a sound receiving unit configured to be located completely within the ear canal;
an alternative transduction unit configured to transmit sound signals to an ear;
the sound receiving unit and the alternative transduction unit being in communication with the processing circuitry.

11. The hearing instrument of claim 10, wherein the sound receiving unit is a microphone or an acoustic tube coupled to a microphone.

12. The hearing instrument of claim 10, wherein the alternative transduction unit is a cochlear implant.

13. The hearing instrument of claim 10, wherein the alternative transduction unit is a bone anchored hearing unit.

14. The hearing instrument of claim 10, wherein the alternative transduction unit is a middle ear implant.

15. The hearing instrument of claim 10, further comprising a speaker, the speaker being in communication with the processing circuitry and operable to transmit sounds to the ear in conjunction with the alternative transduction unit.

16. A hearing instrument comprising:
a main housing configured to be located outside of an ear canal, the main housing including processing circuitry operable to process signals;
a first sound receiving unit configured to be located completely within the ear canal;
a second sound receiving unit spatially separate from the first sound receiving unit;
the first and second sound receiving units being in communication with the processing circuitry.

17. The hearing instrument of claim 16, wherein the first sound receiving unit is a microphone or acoustic tube coupled to a microphone.

18. The hearing instrument of claim 16, wherein the second sound receiving unit is a microphone or acoustic tube coupled to a microphone.

19. The hearing instrument of claim 16, wherein the second sound receiving unit is located in or on the main housing.

20. The hearing instrument of claim 16, wherein the main housing includes a communications unit.

21. The hearing instrument of claim 20, wherein the communications unit is configured to transmit or receive wireless signals.

22. The hearing instrument of claim 20, wherein the communications unit is configured to transmit and receive wireless signals.

23. The hearing instrument of claim 22, wherein the communications unit is configured to wirelessly communicate with another hearing instrument.

24. The hearing instrument of claim 23, wherein communication between the hearing instruments is utilized to assist in feedback cancellation.

25. The hearing instrument of claim 23, wherein communication between the hearing instruments is utilized to assist in directional processing.

26. The hearing instrument of claim 16, further comprising a sound emitting unit to be located completely within the ear canal and be in communication with the processing circuitry.

27. The hearing instrument of claim 26, wherein the sound emitting unit is a speaker or an acoustic tube coupled to a speaker.

28. The hearing instrument of claim 26, further comprising an acoustic blocker configured to at least substantially occlude the ear canal and isolate the sound emitting unit from the sound receiving unit.

29. The hearing instrument of claim 16, further comprising a cochlear implant configured to be in communication with the processing circuitry.

30. The hearing instrument of claim 16, further comprising a bone anchored hearing unit configured to be in communication with the processing circuitry.

31. The hearing instrument of claim 16, further comprising a middle ear implant configured to be in communication with the processing circuitry.

32. The hearing instrument of claim 16, wherein the processing circuitry is configured to use the input from the first and second sound receiving units to provide directional processing.

33. The hearing instrument of claim 16, wherein the processing circuitry is configured to use the input from the first and second sound receiving units to provide feedback cancellation.

34. A hearing instrument comprising:
a main housing configured to be located outside of an ear canal, the main housing including processing circuitry operable to process signals;
a first sound receiving unit configured to be located completely within the ear canal;
a sound emitting unit configured to be located completely within the ear canal;
an acoustic blocker configured to at least substantially occlude the ear canal and isolate the sound emitting unit from the first sound receiving unit; and
a second sound receiving unit located between the acoustic blocker and the ear drum;
the first and second sound receiving units and the sound emitting unit being in communication with the processing circuitry.

35. The hearing instrument of claim 34, wherein the first sound receiving unit is a microphone or an acoustic tube coupled to a microphone.

36. The hearing instrument of claim 34, wherein the second sound receiving unit is a microphone or an acoustic tube coupled to a microphone.

37. The hearing instrument of claim 34, wherein the sound emitting unit is a speaker or an acoustic tube coupled to a speaker.

38. The hearing instrument of claim 34, wherein the second sound receiving unit is used in conjunction with the sound emitting unit to provide occlusion cancellation.

39. The hearing instrument of claim 34, wherein the second sound receiving unit is used in conjunction with the first sound receiving unit to provide feedback cancellation.

40. The hearing instrument of claim 34, further comprising a second processing circuitry unit located in the ear canal.

41. The hearing instrument of claim 40, wherein the second processing circuitry unit is used in conjunction with the second sound receiving unit and the sound emitting unit to provide occlusion cancellation.

42. The hearing instrument of claim 40, wherein the second processing circuitry unit is used in conjunction with the first and second sound receiving units to provide feedback cancellation.
